(19) United States
(12) Patent Application Publication
(10) Pub. No.: US 2025/0201718 A1
(43) Pub. Date: Jun. 19, 2025

(54) INTERCONNECT SUBSTRATE AND METHOD OF MAKING THE SAME

(71) Applicant: SHINKO ELECTRIC INDUSTRIES CO., LTD., Nagano (JP)

(72) Inventor: Takashi ARAI, Nagano (JP)

(21) Appl. No.: 18/971,694

(22) Filed: Dec. 6, 2024

(30) Foreign Application Priority Data
Dec. 15, 2023 (JP) 2023-212036

(51) Int. Cl. H01L 23/532; H01L 23/528

(52) U.S. Cl. CPC H01L 23/53295; H01L 23/5283

(57) ABSTRACT

An interconnect substrate includes a first insulating layer having a cavity formed therein, an electronic component including an insulating substrate and a pad provided on one side of the insulating substrate, the electronic component being arranged in the cavity, with the pad facing an opening of the cavity, and a second insulating layer disposed on the first insulating layer and in the cavity, wherein an upper surface and side surfaces of the pad have areas situated outside the insulating substrate, wherein at least a part of the areas is covered with the second insulating layer, and wherein a roughness a surface of the pad covered with the second insulating layer is larger than a roughness of a surface of the pad not covered with the second insulating layer.

### CROSS-REFERENCE TO RELATED APPLICATIONS

The present application is based on and claims priority to Japanese Patent Application No. 2023-212036 filed on Dec. 15, 2023, with the Japanese Patent Office, the entire contents of which are incorporated herein by reference.

### FIELD

The disclosures herein relate to interconnect substrates and methods of making an interconnect substrate.

### BACKGROUND

Interconnect substrates incorporating electronic components are known in the art. For example, an interconnect substrate may include a first insulating layer, a second insulating layer arranged under the first insulating layer and having a conductor layer formed on the upper surface thereof, a cavity penetrating both the first insulating layer and the conductor layer to expose the second insulating layer at the bottom, and an electronic component accommodated in the cavity (see Patent Document 1, for example).

In such an interconnect substrate, it is preferable to strengthen adhesion between the pads of the electronic component and the insulating layer the pads covering from the viewpoint of the reliability of the interconnect substrate.

Accordingly, there may be a need to improve adhesion between the pads of an electronic component and the insulating layer covering the pads in an interconnect substrate incorporating the electronic component.

### RELATED ART DOCUMENT

### [Patent Document]

[Patent Document 1] Japanese Laid-open Patent Publication No. 2020-184596

### SUMMARY

According to an aspect of the embodiment, an interconnect substrate includes a first insulating layer having a cavity formed therein, an electronic component including an insulating substrate and a pad provided on one side of the insulating substrate, the electronic component being arranged in the cavity, with the pad facing an opening of the cavity, and a second insulating layer disposed on the first insulating layer and in the cavity, wherein an upper surface and side surfaces of the pad have areas situated outside the insulating substrate, wherein at least a part of the areas is covered with the second insulating layer, and wherein a roughness of a surface of the pad covered with the second insulating layer is larger than a roughness of a surface of the pad not covered with the second insulating layer.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIGS. 1A and 1B are cross-sectional views illustrating an example of an interconnect substrate according to a first embodiment;

FIGS. 2A through 2D are drawings illustrating an example of a manufacturing process of the interconnect substrate according to the first embodiment;

FIGS. 3A through 3D are drawings illustrating the example of the manufacturing process of the interconnect substrate according to the first embodiment;

FIGS. 4A through 4D are drawings illustrating the example of the manufacturing process of the interconnect substrate according to the first embodiment;

FIGS. 5A through 5D are drawings illustrating the example of the manufacturing process of the interconnect substrate according to the first embodiment;

FIG. 6 is a cross-sectional view illustrating an example of a portion of an interconnect substrate according to a comparative example;

FIGS. 7A through 7C are drawings illustrating another example of a manufacturing process of the interconnect substrate according to the first embodiment; and

FIG. 8 a is cross-sectional view illustrating an example of a portion of an interconnect substrate according to a second embodiment.

### DESCRIPTION OF EMBODIMENTS

In the following, embodiments of the invention will be described with reference to the accompanying drawings. In these drawings, the same components are referred to by the same reference numerals, and duplicate descriptions thereof may be omitted.

### First Embodiment

### [Structure of Interconnect Substrate]

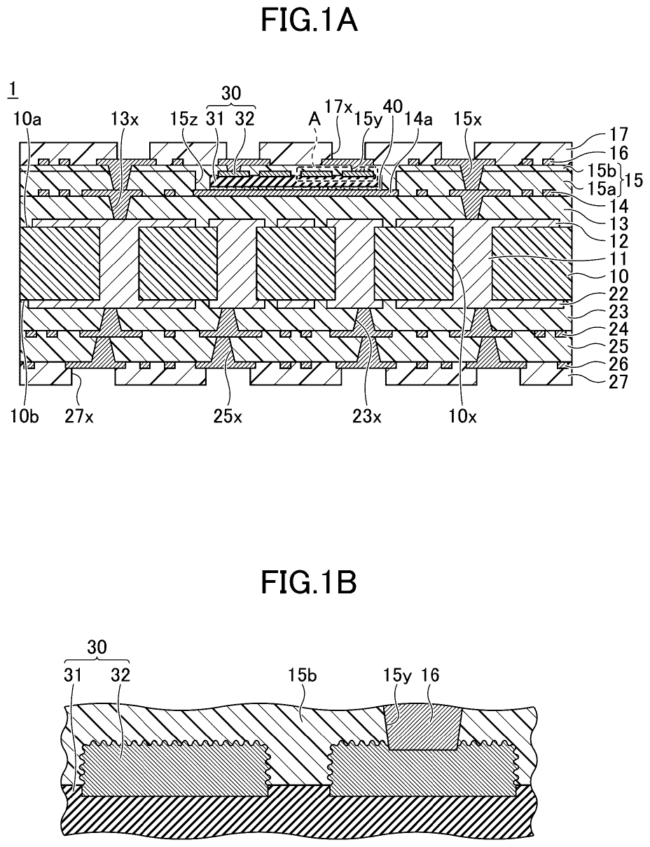

FIGS. 1A and 1B are cross-sectional views illustrating an interconnect substrate according to a first embodiment. FIG. 1A is an overall view, and FIG. 1B is an enlarged view of a portion A in FIG. 1A.

Referring to FIGS. 1A and 1B, an interconnect substrate 1 is structured such that interconnect layers and insulating layers are laminated on both surfaces of a core layer 10.

Specifically, the interconnect substrate 1 is structured such that an interconnect layer 12, an insulating layer 13, an interconnect layer 14, an insulating layer 15, an interconnect layer 16, and a solder resist layer 17 are sequentially laminated on the first surface 10a of the core layer 10. On the second surface 10b of the core layer 10, an interconnect layer 22, an insulating layer 23, an interconnect layer 24, an insulating layer 25, an interconnect layer 26, and a solder resist layer 27 are sequentially laminated.

In the first embodiment, for the sake of convenience, the solder resist layer 17 side of the interconnect substrate 1 is referred to as an upper side or a first side, and the solder resist layer 27 side is referred to as a lower side or a second side. The surface of a member on the upper side thereof is referred to as the first surface or the upper surface, and the surface of the member on the lower side thereof is referred to as the second surface or the lower surface. However, the interconnect substrate 1 may be positioned upside down when used, or may be arranged at any angle. The plan view refers to the view of an object as seen from the direction normal to the first surface 10a of the core layer 10, and the plane shape refers to the shape of an object as seen from the direction normal to the first surface 10a of the core layer 10.

The core layer 10 may be, for example, a glass-epoxy substrate in which a glass cloth is impregnated with an insulating resin such as an epoxy-based resin. The core layer 10 may also be, for example, a substrate in which a woven fabric or a nonwoven fabric such as a glass fiber, a carbon fiber, or an aramid fiber is impregnated with an epoxy-based resin or the like. The thickness of the core layer 10 is, for example, about 60 to 1000 μm. The core layer 10 has at least one through hole 10x that penetrates the core layer 10 in the thickness direction. The plane shape of the through hole 10x is, for example, circular.

The interconnect layer 12 is formed on the first surface 10a of the core layer 10. The interconnect layer 22 is formed on the second surface 10b of the core layer 10. The interconnect layer 12 and the interconnect layer are electrically connected by at least one through interconnect 11 formed in the through hole 10x. The interconnect layers 12 and 22 are patterned into predetermined plane shapes. As the material of the interconnect layers 12 and 22 and the through interconnect 11, for example, copper (Cu) or the like may be used. The thickness of the interconnect layers 12 and 22 is, for example, about 10 to 40 μm. The interconnect layers 12, 22 and the through interconnect 11 may be formed together as a single seamless structure.

The insulating layer 13 is formed on the first surface 10a of the core layer 10 so as to cover the interconnect layer 12. As the material of the insulating layer 13, for example, an insulating resin mainly composed of an epoxy-based resin or a polyimide-based resin may be used. The thickness of the insulating layer 13 may be, for example, about 30 to 40 μm. The insulating layer 13 may contain a filler such as silica (SiO₂).

At least one via hole 13x that penetrates the insulating layer 13 and reaches the upper surface of the interconnect layer 12 is formed in the insulating layer 13. The via hole 13x may be an inverted frustoconical recess whose opening diameter toward the insulating layer 15 is larger than the opening diameter at the bottom on the upper surface of the interconnect layer 12.

The interconnect layer 14 is formed on the first side of the insulating 13. layer The interconnect layer 14 includes a via interconnect filling the via hole 13x and an interconnect pattern formed on the upper surface of the insulating layer 13. The interconnect pattern is electrically connected to the interconnect layer 12 through the via interconnect. The interconnect pattern may include an electronic component mounting pad 14a formed on the upper surface of the insulating layer 13. The material of the interconnect layer 14 and the thickness of the interconnect pattern may be, for example, the same as those of the interconnect layer 12.

The insulating layer 15 includes a first insulating layer 15a and a second insulating layer 15b. The thickness of the insulating layer 15 may be, for example, the same as that of the insulating layer 13. The first insulating layer 15a is formed so as to cover the upper surface and the side surfaces of the interconnect layer 14. The material of the first insulating layer 15a may be, for example, the same as that of the insulating layer 13. The first insulating layer 15a may contain a filler such as silica (SiO₂).

A cavity 15z is formed in the first insulating layer 15a to reach the upper surface of the electronic component mounting pad 14a. An electronic component 30 is disposed in the cavity 15z. The electronic component 30 includes an insulating substrate 31 and pads 32 provided on the first side of the insulating substrate 31. The electronic component 30 is arranged on the upper surface of the electronic component mounting pad 14a in the cavity 15z such that the pads 32 face the opening of the cavity 15z. An adhesive layer 40 may be provided between the lower surface of the insulating substrate 31 and the upper surface of the electronic component mounting pad 14a. The upper surfaces of the pads 32 and the upper surface of the first insulating layer 15a may have the same or different heights. When the heights are different, it does not matter whether the upper surfaces of the pads 32 are higher or the upper surface of the first insulating layer 15a is higher.

The insulating substrate 31 of the electronic component 30 may be formed of, for example, an oxide or nitride of silicon. The oxide of silicon may be, for example, SiO₂. The nitride of silicon may be, for example, SiN. The thickness of the insulating substrate 31 may be, for example, about 6 to 30 μm. Each of the pads 32 is made of, for example, the same material as a single seamless structure. That is, the pads 32 are original parts of the electronic component 30, and do not include a metal layer or the like laminated on the pads 32 after the electronic component 30 is obtained. Examples of the material of the pads 32 include copper, a copper alloy, aluminum, and an aluminum alloy. The thickness of the pads 32 may be, for example, about 5 to 15 μm.

One or more electronic components 30 may be incorporated in the interconnect substrate 1. The electronic component 30 may be a passive component or an active component. When a plurality of electronic components 30 are incorporated in the interconnect substrate 1, the electronic components 30 may all be passive components, or may all be active components, or may be a mixture of both. The electronic component 30 may be, for example, an IPD (integrated passive device), a semiconductor chip, a capacitor, an inductor, a resistor, or the like. The plane shape of the cavity 15z may be, for example, geometrically similar to the plane shape of the electronic component 30, and its size is larger than that of the electronic component 30.

The upper surface and the side surfaces of each of the pads 32 of the electronic component 30 have portions situated outside the insulating substrate 31. In the example illustrated in FIG. 1B, the upper surface of each of the pads 32 and portions of the side surfaces near the upper surface are situated outside the insulating substrate 31. Portions of the side surfaces of each of the pads 32 near the lower surface thereof are covered with the insulating substrate 31.

The second insulating layer 15b is a buried insulation layer disposed in the cavity 15z and on the first insulating layer 15a. The second insulating layer 15b covers the electronic component 30 in the cavity 15z and extends upward beyond the cavity 15z to cover the upper surface of the first insulating layer 15a. The material of the second insulating layer 15b may be substantially the same as that of the first insulating layer 15a, for example. The second insulating layer 15b may alternatively be formed of a material different from that of the first insulating layer 15a. The thickness of the second insulating layer 15b at the portion laminated on the upper surface of the first insulating layer 15a may be, for example, about 10 to 20 μm. The second insulating layer 15b may contain a filler such as silica (SiO₂).

At least a part of the upper surface and the side surfaces of each of the pads 32 situated outside the insulating substrate 31 is covered with the second insulating layer 15b. In the example illustrated in FIG. 1B, the upper surfaces of the pads 32 situated outside the insulating substrate 31, except for the portion situated in the via hole 15y, are covered with the second insulating layer 15b. The portions of the side surfaces of the pads 32, namely, the portions situated outside the insulating substrate 31, are all covered with the second insulating layer 15b.

The surfaces of the pads 32 covered with the second insulating layer 15b are roughened surfaces. That is, the roughness of the surfaces of the pads 32 covered with the second insulating layer 15b is greater than the roughness of the surfaces of the pads 32 not covered with the second insulating layer 15b. In FIG. 1B, the surfaces indicated by wavy lines are roughened surfaces. The roughness of the upper surfaces of the pads 32 outside the via hole 15y and the portions of the side surfaces of the pads 32 close to the upper surface, namely, all the surfaces indicated by wavy lines, is greater than the roughness of the upper surface of the pad 32 situated inside the via hole 15y, the portions of the side surfaces of the pads 32 close to the lower surface, and the lower surfaces of the pads 32, namely, all the surfaces not indicated by wavy lines. Alternatively, all of the side surfaces of the pads 32 in FIG. 1B may be situated outside the insulating substrate 31 and covered with the second insulating layer 15b. In this case, all of the side surfaces of the pads 32 become roughened surfaces. The roughness of the roughened surfaces of the pads 32 may be, for example, about 50 to 300 nm in terms of surface roughness Ra.

The insulating layer 15 has at least one via holes 15x that penetrates the first insulating layer 15a and the second insulating layer 15b to reach the upper surface of the interconnect layer 14. The insulating layer 15 has at least one via hole 15y that penetrates the second insulating layer 15b to reach a part of the upper surface of at least one of the pads 32 of the electronic component 30. The via holes 15x and 15y may be inverted frustoconical recesses whose opening diameters toward the solder resist layer 17 are larger than the respective opening diameters at the bottoms on the upper surface of the interconnect layer 14 and on the upper surface of the pads 32. The roughness of the upper surface of any one of the pads 32 situated at the bottom of the via hole 15y may be, for example, about 300 nm or less in terms of the surface roughness Ra.

The interconnect layer 16 is formed on the first side of the insulating layer 15. The interconnect layer 16 includes via interconnects filling the via holes 15x and 15y, and includes interconnect patterns formed on the upper surface of the insulating layer 15. The interconnect patterns include a portion electrically connected to the interconnect layer 14 through the via interconnect filling in the via hole 15x. The interconnect patterns include a portion electrically connected to one of the pads 32 of the electronic component 30 through the via interconnect filling the via hole 15y. The material of the interconnect layer 16 and the thickness of the interconnect patterns may be the same as those of the interconnect layer 12, for example.

The solder resist layer 17 is a protective insulating layer located at the outermost position on the first side of the interconnect substrate 1, and is formed on the upper surface of the insulating layer 15 so as to cover the interconnect layer 16. The solder resist layer 17 may be formed of, for example, a photosensitive epoxy-based insulating resin or acrylic-based insulating resin. The thickness of the solder resist layer 17 is, for example, about 15 to 35 μm.

The solder resist layer 17 has at least one opening 17x. The opening 17x penetrates the solder resist layer 17 to expose the upper surface of the interconnect layer 16. The interconnect layer 16 exposed in the opening 17x may be used as a pad for electrical connection to an electronic component such as a semiconductor chip, for example.

The surface of the interconnect layer 16 exposed in the opening 17x may have a metal layer formed thereon, or may have an organic film formed thereon by applying an oxidation prevention treatment such as OSP (organic solderability preservative) treatment. Examples of the metal layer include an Au layer, a Ni/Au layer (a metal layer in which a Ni layer and an Au layer are laminated in this order), a Ni/Pd/Au layer (a metal layer in which a Ni layer, a Pd layer, and an Au layer are laminated in this order), and a Sn layer.

The insulating layer 23 is formed on the second surface 10b of the core layer 10 so as to cover the interconnect layer 22. The material and thickness of the insulating layer 23 may be the same as those of the insulating layer 13, for example. The insulating layer 23 may contain a filler such as silica (SiO₂).

At least one via hole 23x penetrating the insulating layer 23 and reaching the lower surface of the interconnect layer 22 is formed in the insulating layer 23. The via hole 23x may be a frustoconical recess whose opening diameter toward the insulating layer 25 is larger than the opening diameter at the top on the lower surface of the interconnect layer 22.

The interconnect layer 24 is formed on the second side of the insulating layer 23. The interconnect layer 24 includes a via interconnect filling the via hole 23x and an interconnect pattern formed on the lower surface of the insulating layer 23. The interconnect pattern is electrically connected to the interconnect layer 22 through the via interconnect. The material and thickness of the interconnect layer 24 may be the same as those of the interconnect layer 12, for example.

The insulating layer 25 is formed on the lower surface of the insulating layer 23 so as to cover the interconnect layer 24. The material and thickness of the insulating layer 25 may be the same as those of the insulating layer 13, for example. The insulating layer 25 may contain a filler such as silica (SiO₂).

At least one via hole 25x is formed in the insulating layer 25 to penetrate the insulating layer 25 and reach the lower surface of the interconnect layer 24. The via hole 25x may be a frustoconical recess whose opening diameter toward the solder resist layer 27 side is larger than the opening diameter at the top on the lower surface of the interconnect layer 24.

The interconnect layer 26 is formed on the second side of the insulating layer 25. The interconnect layer 26 includes a via interconnect filling the via hole 25x and an interconnect pattern formed on the lower surface of the insulating layer 25. The interconnect pattern is electrically connected to the interconnect layer 24 through the via interconnect. The material and thickness of the interconnect layer 26 may be, for example, the same as those of the interconnect layer 12.

The solder resist layer 27 is a protective insulating layer at the outermost position on the second side of the interconnect substrate 1, and is formed to cover the interconnect layer 26 on the lower surface of the insulating layer 25. The material and thickness of the solder resist layer 27 may be the same as those of the solder resist layer 17, for example. The solder resist layer 27 has at least one opening 27x, and a part of the lower surface of the interconnect layer 26 is exposed in the opening 27x. The plane shape of the opening 27x may be circular, for example. The interconnect layer 26 exposed in the opening 27x may be used as a pad for electrical connection to a mounting substrate such as a mother board. According to need, the lower surface of the interconnect layer 26 exposed in the opening 27x may have a metal layer formed thereon similarly to the one previously described, or may be subjected to oxidation prevention treatment such as OSP treatment.

### [Method of Making Interconnect Substrate]

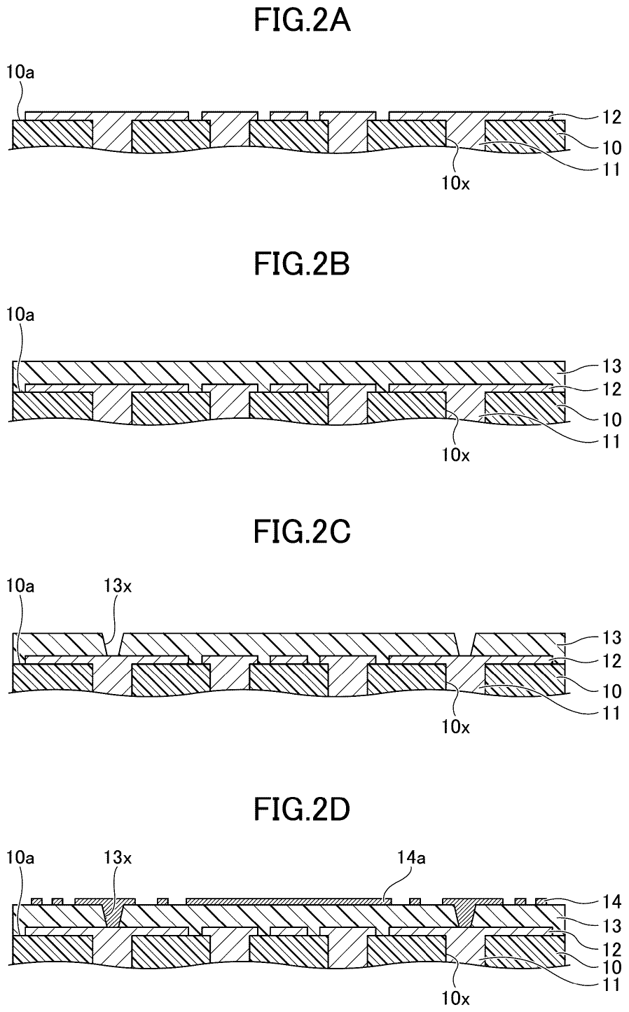

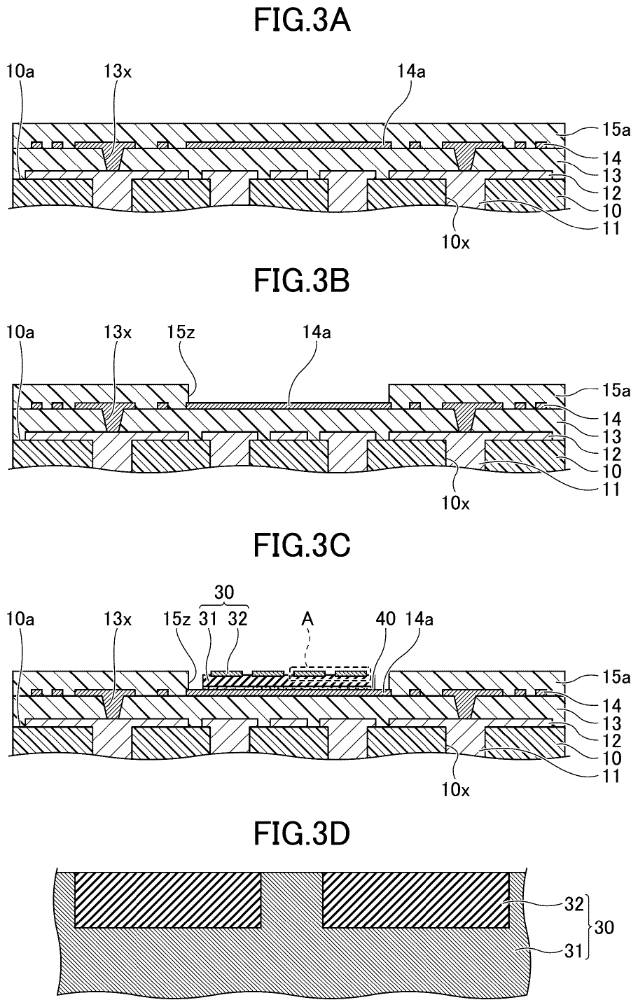

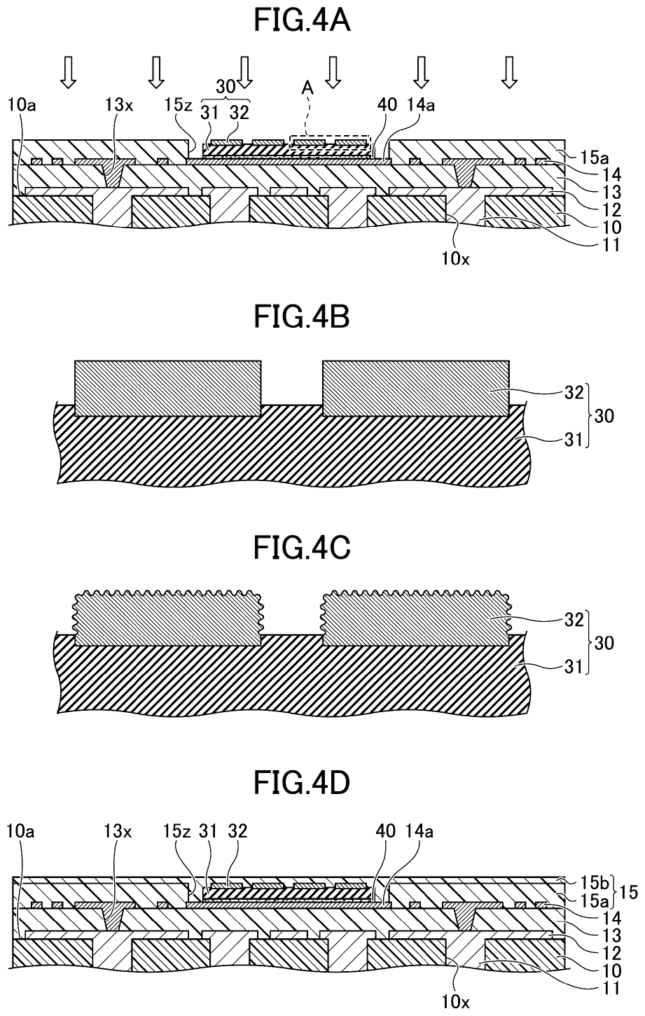

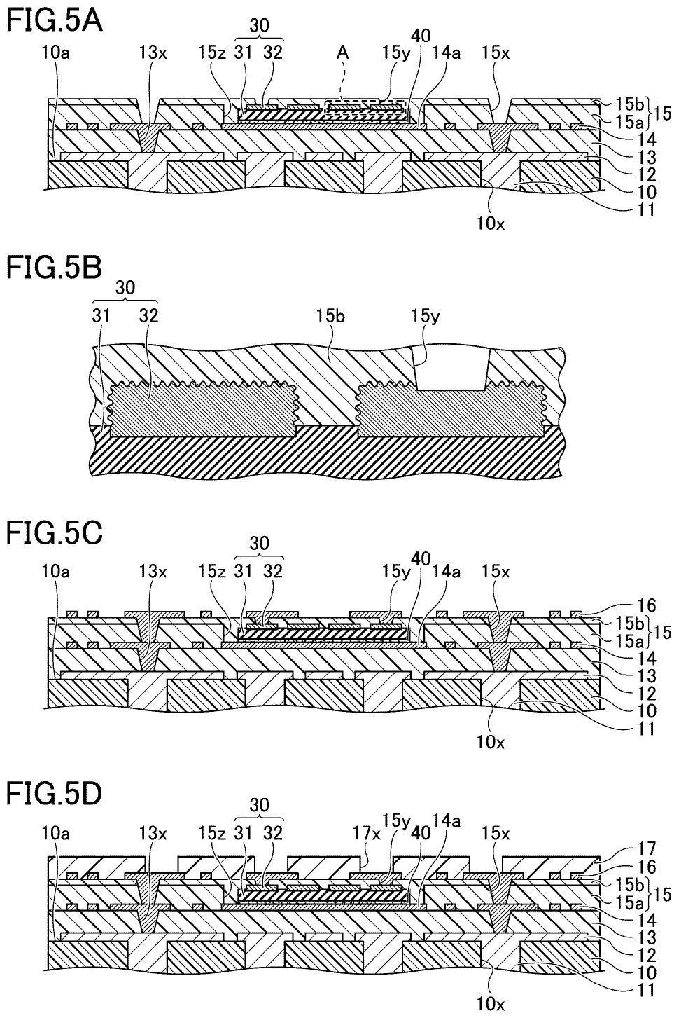

FIGS. 2A through 2D to FIGS. 5A through 5D are drawings illustrating the process sequence for making the interconnect substrate according to the first embodiment, and are cross-sectional views corresponding to FIGS. 1A and 1B. FIG. 3D is an enlarged view of a portion A in FIG. 3C. FIGS. 4B and 4C are enlarged views of a portion A in FIG. 4A. FIG. 5B is an enlarged view of a portion A in FIG. 5A.

Since the structures on the first surface 10a side and the second surface 10b side of the core layer 10 are made by substantially the same process sequence, only the first surface 10a side of the core layer 10 will be illustrated and described here. Although the description given below is directed to an example of a process sequence for fabricating one interconnect substrate, the process sequence may alternatively fabricate a plurality of portions to become respective interconnect substrates and then divide these portions into individual interconnect substrates.

First, in the step illustrated in FIG. 2A, the core layer 10 having the through interconnects 11 and the interconnect layer 12 formed thereon is prepared. Specifically, a laminated plate is prepared by, for example, forming a flat copper foil which is not patterned on the first surface 10a of the core layer 10 such as a glass epoxy substrate. Subsequently, the copper foil of the prepared laminated plate is thinned as necessary, and the through holes 10x which penetrate the core layer 10 and the copper foil are formed by a laser processing method using a CO₂ laser or the like.

A desmearing process is performed as necessary to remove resin residues of the core layer 10 adhered to the inner surfaces of the through holes 10x. A seed layer (copper or the like) which covers the copper foil and the inner surfaces of the through holes 10x is then formed by, for example, an electroless plating method or a sputtering method. An electroplating layer (copper or the like) is formed on the seed layer by an electroplating method, with the seed layer serving as the conductive layer for current. As a result, the through holes 10x are filled with the electroplating layer formed on the seed layer, and the interconnect layer 12 in which the copper foil, the seed layer, and the electroplating layer are laminated is formed on the first surface 10a of the core layer 10. Thereafter, the interconnect layer 12 is patterned into a predetermined plane shape by a subtractive method or the like.

In the step illustrated in FIG. 2B, a semi-cured epoxy-based resin film or the like is laminated on the first surface 10a of the core layer 10 so as to cover the interconnect layer 12, and cured to form the insulating layer 13. Alternatively, instead of laminating the epoxy-based resin film or the like, an epoxy-based resin liquid or paste or the like may be applied and cured to form the insulating layer 13. The material and thickness of the insulating layer 13 are as previously described.

In the step illustrated in FIG. 2C, via holes 13x are formed in the insulating layer 13 to penetrate the insulating layer 13 and expose the upper surface of the interconnect layer 12. The via holes 13x may be formed by, for example, a laser processing method using a CO₂ laser or the like. After the via are formed, a desmearing process is holes 13x preferably performed to remove resin residues adhering to the surface of the interconnect layer 12 exposed at the bottoms of the via holes 13x.

In the step illustrated in FIG. 2D, the interconnect layer 14 is formed on the first side of the insulating layer 13. The interconnect layer 14 includes via interconnects filling in the via holes 13x and interconnect patterns formed on the upper surface of the insulating layer 13. The interconnect patterns may include the electronic component mounting pad 14a. The material of the interconnect layer 14 and the thickness of the interconnect patterns may be the same as those of the interconnect layer 12, for example. The interconnect layer 14 is electrically connected to the interconnect layer 12 situated at the bottom of the via holes 13x.

The interconnect layer 14 may be formed using any type of interconnect formation method such as a semi-additive method or a subtractive method. For example, when the interconnect layer 14 is formed by a semi-additive method, a seed layer is formed by electroless plating of copper on the surface of the insulating layer 13 including the inner walls of the via holes 13x and on the surface of the interconnect layer 12 exposed in the via holes 13x. Next, a plating resist pattern having openings matching the respective shapes of the: interconnect layer 14 is formed on the seed layer, followed by depositing an electroplating layer on the seed layer exposed at the openings of the plating resist pattern by copper electroplating, with the seed layer serving as the conductive layer for current. Thereafter, the plating resist pattern is removed, and, then, etching using the electroplating layer as a mask is performed to remove the seed layer exposed outside the electroplating layer, thereby obtaining the interconnect layer 14.

In the step illustrated in FIG. 3A, the first insulating layer 15a is formed on the insulating layer 13 so as to cover the interconnect layer 14. The first insulating layer 15a may be formed, for example, by the same method as the insulating layer 13. The material of the first insulating layer 15a is as previously described.

In the step illustrated in FIG. 3B, the cavity 15z is formed in the first insulating layer 15a so as to penetrate the first insulating layer 15a and expose the upper surface of the electronic component mounting pad 14a. The cavity 15z may be formed, for example, by a laser processing method using a CO₂ laser or the like.

In the steps illustrated in FIGS. 3C and 3D, the electronic component 30 having the insulating substrate 31 and the pads 32 provided on the first side of the insulating substrate 31 is prepared. In the electronic component 30, the upper surfaces of the pads 32 are exposed outside the insulating substrate 31, and the entire side surfaces of the pads 32 are covered with the insulating substrate 31. The upper surfaces of the pads 32 may be flush with the upper surface of the insulating substrate 31, for example. The electronic component 30 is disposed on the upper surface of the electronic component mounting pad 14a exposed in the cavity 15z so that the pads 32 face the opening of the cavity 15z. The electronic component 30 may be temporarily fixed to the upper surface of the electronic component mounting pad 14a via the adhesive layer 40. Alternatively, the electronic component 30 may be placed directly on the upper surface of the electronic component mounting pad 14a.

In the step illustrated in FIGS. 4A and 4B, the electronic component 30 arranged in the cavity 15z is dry-etched from the direction indicated by the arrows to expose at least a part of the side surfaces of the pads 32 from the insulating substrate 31. The dry-etching is performed under the condition that the etching rate of the insulating substrate 31 is sufficiently higher than that of the pads 32. For example, when the insulating substrate 31 is made of SiO₂ or SiN and the pads 32 are made of copper, plasma etching using a fluorine-based etching gas such as carbon tetrafluoride (CF₄) may be selected for the dry etching. A mixed gas of a fluorine-based gas and an oxygen gas may be used as the etching gas. Instead of plasma etching, ion milling or the like may be used. For dry etching, isotropic dry etching or anisotropic dry etching may be used.

The insulating substrate 31 is made of a material whose etching rate in dry etching such as plasma etching is higher than that of the pads 32. By dry etching, thus, the pads 32 are hardly etched and the insulating substrate 31 is selectively etched. As a result, as illustrated in FIG. 4B, the upper surface side of the insulating substrate 31 is abraded and part of the side surfaces of the pads 32 are exposed from the insulating substrate 31. Alternatively, the entire side surfaces of the pads 32 may be exposed from the insulating substrate 31. It may be noted that the upper surface of the first insulating layer 15a is also etched together with the electronic component 30. A mask for preventing etching of the upper surface of the first insulating layer 15a may be arranged.

In the step illustrated in FIG. 4C, the upper surfaces and the side surfaces of the pads 32 exposed outside the insulating substrate 31 are roughened. The roughening of the pads 32 may be performed, for example, by CZ treatment. In the CZ treatment, for example, the pads 32 are etched using a solution whose main component is formic acid to form roughened surfaces. By performing the CZ treatment, the roughness of the upper surfaces and the side surfaces of the pads 32 exposed outside the insulating substrate 31 may be made larger than the roughness of the portions of the pads 32 covered with the insulating substrate 31. The roughening process performed in this step is preferably such that, while the roughness of the portions covered with the insulating substrate 31 is approximately from several nanometers to 50 nm in terms of surface roughness Ra, the roughness of the upper surfaces and the side surfaces of the pads 32 exposed outside the insulating substrate 31 is approximately from 50 nm to 300 nm in terms of surface roughness Ra. Instead of the CZ treatment, the pads 32 may be roughened by other means such as black oxidation treatment (black oxide). It may be noted that the upper surface of the insulating substrate 31 is not roughened by these treatments.

In the step illustrated in FIG. 4D, the second insulating layer 15b is disposed on the first insulating layer 15a and in the cavity 15z, and the roughened upper surfaces and side surfaces of the pads 32 are covered with the second insulating layer 15b. Specifically, a semi-cured film of epoxy-based resin or the like, for example, is laminated to cover the electronic component 30, and cured to form the second insulating layer 15b. Alternatively, instead of laminating the epoxy-based resin film or the like, an epoxy-based resin liquid or paste or the like may be applied and cured to form the second insulating layer 15b. The material of the second insulating layer 15b is as previously described. The combined thickness of the first insulating layer 15a and the second insulating layer 15b may be, for example, the same as that of the insulating layer 13. This step completes the manufacture of the insulating layer 15 formed of the first insulating layer 15a and the second insulating layer 15b.

In the step illustrated in FIG. 5A, the via holes 15x that penetrate the first insulating layer 15a and the second insulating layer 15b and expose the upper surface of the interconnect layer 14 are formed in the insulating layer 15. Further, the via holes 15y that penetrate the second insulating layer 15b and expose the upper surfaces of the pads 32 of the electronic component 30 are formed in the insulating layer 15. The via holes 15x and 15y may each be an inverted frustoconical recess whose opening diameter at the upper of surface the insulating layer 15 is larger than the opening diameter at the bottom on the upper surface of the interconnect layer 14 or on the upper surface of the pads 32. The via holes 15x and 15y may be formed by a laser processing method using, for example, a CO₂ laser, a UV laser, an Excimer laser, or the like. After the via holes 15x and 15y are formed, a desmearing process is preferably performed to remove resin residues adhering to the upper surfaces of the interconnect layer 14 and the pads 32 exposed at the bottom of the via holes 15x and 15y, respectively.

After desmearing, soft etching is preferably performed on the upper surfaces of the interconnect layer 14 and the pads 32 exposed at the bottom of the via holes 15x and 15y, respectively. By the soft etching, the upper surfaces of the interconnect layer 14 and the pads 32 exposed at the bottom of the via holes 15x and 15y become chemically clean, and good conduction with the via interconnect formed in the process described later may be achieved. The soft etching refers to a process that uniformly etches the surface of an object by several micrometers. When the pads 32 are made of copper, soft etching may be performed using, for example, a cupric chloride aqueous solution. By the soft etching, the upper surfaces of the pads 32 exposed at the bottoms of the via holes 15y are made flatter than the upper surfaces of the pads 32 positioned around the via holes 15y. By the soft etching, the upper surfaces of the pads 32 exposed at the bottoms of the via holes 15y are slightly recessed relative to the upper surfaces of the pads 32 situated around the via holes 15y. The soft etching performed in this step is preferably such that the upper surfaces of the pads 32 exposed at the bottoms of the via holes 15y have a surface roughness Ra of about several nanometers to 300 nm.

In the step illustrated in FIG. 5C, the interconnect layer 16 is formed. The interconnect layer 16 includes via interconnects filling the via holes 15x and 15y and interconnect patterns formed on the upper surface of the insulating layer 15. The interconnect patterns include portions electrically connected to the interconnect layer 14 through the via interconnects filling the via holes 15x. The interconnect patterns also include portions electrically connected to the pads 32 of the electronic component 30 through the via interconnects filling the via holes 15y. The interconnect layer 16 may be formed using any type of interconnect forming method such as a semi-additive method or a subtractive method.

In the step illustrated in FIG. 5D, a solder resist layer 17 is formed on the upper surface of the insulating layer 15 so as to cover the interconnect layer 16. The solder resist layer 17 may be formed, for example, by applying a photosensitive epoxy-based insulating resin or acrylic-based insulating resin in liquid or paste form to the upper surface of the insulating layer 15 so as to cover the interconnect layer 16 by a screen-printing method, a roll coating method, a spin coating method, or the like. Alternatively, a photosensitive epoxy-based insulating resin or acrylic-based insulating resin film may be laminated on the upper surface of the insulating layer 15 so as to cover the interconnect layer 16.

The solder resist layer 17 is exposed and developed (i.e., by the photolithography method) to form the openings 17x through the solder resist layer 17 to expose portions of the upper surface of the interconnect layer 16. The plane shape of each opening 17x may be, for example, circular. In this case, the diameter of the opening 17x may be selected in accordance with an object to be connected (e.g., semiconductor chip).

In this step, the previously described metal layer may be formed on the upper surface of the interconnect layer 16 exposed at the bottom of the openings 17x by, for example, electroless plating. Alternatively, oxidation prevention treatment such as OSP treatment may be performed instead of forming the metal layer. By performing the steps described heretofore, the effective of manufacture the interconnect substrate 1 is achieved.

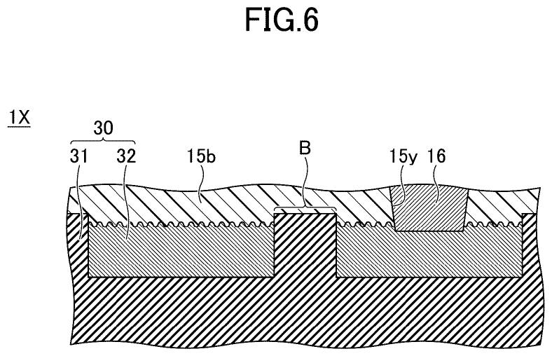

FIG. 6 a cross-sectional view is illustrating a portion of an interconnect substrate according to a comparative example, and illustrates a cross section corresponding to FIG. 1B. In an interconnect substrate 1X illustrated in FIG. 6, all of the side surfaces of pads 32 are covered with an insulating substrate 31, and the upper surfaces of the pads 32 situated outside the insulating substrate 31 are roughened surfaces. The upper surface of the insulating substrate 31 is positioned above the upper surfaces of the pads 32. In this case, good adhesion is obtained between the upper surfaces of the pads 32 and the second insulating layer 15b.

A region B located between the adjacent pads 2 on the upper surface of the insulating substrate 31 is not a roughened surface, so that good adhesion is not obtained between the region B and the second insulating layer 15b. Because of this, a gap easily develops in the region B between the upper surface of the insulating substrate 31 and the second insulating layer 15b. For example, if the plating solution used to form the interconnect layer 16 enters this gap, there is a risk of short-circuiting between the adjacent pads 32. If the pitch between the adjacent pads 32 is relatively wide (for example, 50 μm or more), such a problem is unlikely to occur. However, the pitch between the adjacent pads 32 has tended to narrow in recent years. In particular, when the pitch between the adjacent pads 32 is 40 μm or less, the risk of short-circuiting between the adjacent pads 32 cannot be ignored.

In contrast, the interconnect substrate 1 illustrated in FIG. 1B is such that the portions of the side surfaces of the pads 32 toward the upper surface are situated outside the insulating substrate 31 and are formed as roughened surfaces. This makes the adhesion between the pads 32 and the second insulating layer 15b stronger than in the case illustrated in FIG. 6. That is, an increase in the bonding area between the roughened surfaces of the pads 32 and the second insulating layer 15b improves the adhesion between the pads 32 and the second insulating layer 15b covering the pads 32, as compared with the case illustrated in FIG. 6. As a result, a gap becomes unlikely to develop between the upper surface of the insulating substrate 31 and the second insulating layer 15b, which effectively suppresses the intrusion of the plating solution used for forming the interconnect layer 16, thereby improving the reliability of the interconnect substrate 1.

Further, the upper surface of the insulating substrate 31 positioned between the adjacent pads 32 illustrated in FIG. 1B is positioned below the upper surfaces of the pads 32. This arrangement increases the distance for the placing solution to reach the adjacent pads 32, so that even if the intrusion of the plating solution occurs, the possibility of short-circuiting between the adjacent pads 32 is reduced.

As described above, the interconnect substrate 1 is structured such that short-circuiting is unlikely to occur between the adjacent pads 32 of the electronic component 30, which allows the pitch of the adjacent pads 32 to be narrowed. For example, even when the pitch between the adjacent pads 32 is 40 μm or less, a strong short-circuit prevention capability is effectively obtained, as opposed to the structure illustrated in FIG. 6.

### <First Variation of First Embodiment>

The first variation of the first embodiment is directed to another example of the manufacturing process of the interconnect substrate according to the first embodiment. In connection with the first variation of the first embodiment, descriptions of the same components as those of the already described embodiment may be omitted.

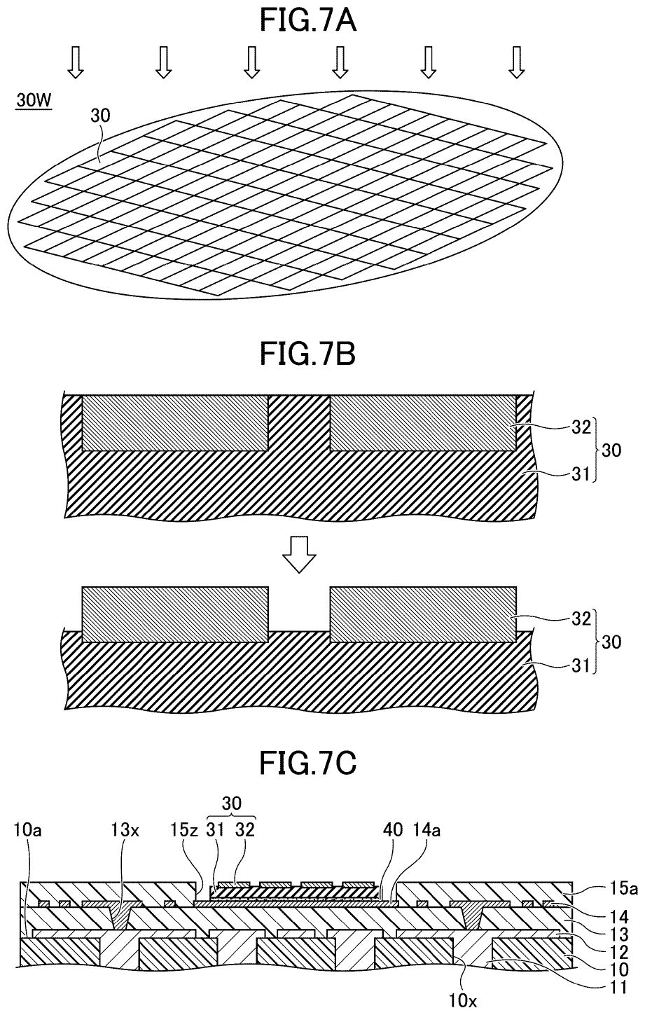

FIGS. 7A through 7C are drawings illustrating another example of the manufacturing process of the interconnect substrate according to the first embodiment. The steps illustrated in FIGS. 3C to 4A of the first embodiment may be replaced with the steps illustrated in FIGS. 7A through 7C.

First, the same steps as those illustrated in FIGS. 2A to 3B of the first embodiment are performed. Next, in the step illustrated in FIGS. 7A and 7B, an electronic component 30 is dry-etched to expose at least a part of the side surfaces of the pads 32 from the insulating substrate 31. Specifically, a wafer 30W having a plurality of electronic components 30 arranged therein is prepared, and the side of the wafer 30W on which the pads 32 are situated is dry-etched from the direction indicated by the arrows. A portion of one of the electronic components 30 prior to dry-etching is illustrated above the arrow in FIG. 7B, and the portion of the one of the electronic components 30 after dry-etching is illustrated below the arrow in FIG. 7B. In each of the electronic components 30 arranged in the wafer 30W, the lower surfaces and the side surfaces of the pads 32 are covered with the insulating substrate 31 before dry etching, and the upper surfaces are exposed outside the insulating substrate 31, as illustrated above the arrow in FIG. 7B. The upper surface of the insulating substrate 31 and the upper surfaces of the pads 32 are flush with each other, for example.

In each of the electronic components 30 arranged in the wafer 30W, the insulating substrate 31 having a high etching rate relative to the pads 32 is selectively removed by dry etching. After dry etching, thus, at least a part of the side surfaces and the upper surfaces of the pads 32 are exposed outside the insulating substrate 31, as illustrated in FIG. 7B.

The steps corresponding to those illustrated in FIGS. 2A to 3B of the first embodiment may be performed before or after, or performed in parallel with, the step illustrated in FIGS. 7A and 7B.

In the step illustrated in FIG. 7C, after the dry etching step illustrated in FIGS. 7A and 7B, each electronic component 30 is arranged in the cavity 15z so that the pads 32 faces the opening of the cavity 15z. More specifically, the electronic components 30 are singulated from the wafer 30W, and each of the electronic components 30 is arranged in the cavity 15z in the same manner as in the step illustrated in FIG. 3C. Thereafter, the interconnect substrate 1 is obtained by carrying out the steps from FIG. 4C onwards as in the first embodiment.

In the step illustrated in FIGS. 4A and 4B of the first embodiment, the upper surface of the first insulating layer 15a is dry-etched together with the pads 32 of the electronic component 30. In contrast, only the insulating substrate 31 of the electronic component 30 is dry-etched in the step illustrated in FIGS. 7A and 7B, so that the upper surface of the first insulating layer 15a is not a dry-etched surface in the step illustrated in FIG. 7C. In consideration of this, either the step illustrated in FIGS. 4A and 4B or the step illustrated in FIGS. 7A and 7B may be selected depending on whether the first insulating layer 15a needs dry-etching.

It may be noted that the step illustrated in FIG. 4C of the first embodiment may be performed between the step illustrated in FIGS. 7A and 7B and the step illustrated in FIG. 7C.

### Second Embodiment

A second embodiment is directed to an example in which the lower surfaces of the pads of the electronic component are partially roughened. In connection with the second embodiment, descriptions of the same components as those of the embodiment previously described may be omitted.

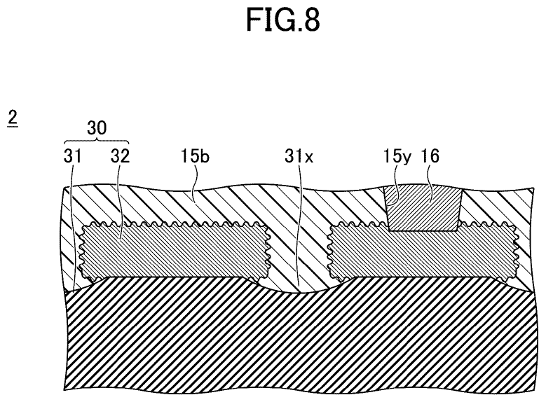

FIG. is a 8 cross-sectional view illustrating a portion of an interconnect substrate according to the second embodiment, and illustrates a cross-section corresponding to FIG. 1B. In an interconnect substrate 2 illustrated in FIG. 8, the insulating substrate 31 of the electronic component 30 is provided with at least one recess 31x for exposing a portion of the outer peripheral area of the lower surface of each of the adjacent pads 32. The outer peripheral area portion of the lower surface of each pad 32 exposed in the recess 31x is roughened to the same degree as the upper surfaces and the side surfaces of the pads 32. The entire side surfaces and the outer peripheral area portions of the lower surfaces of the adjacent pads 32 are covered with the second insulating layer 15b. In the cross-sectional view, the depth of the recess 31x is deepest in the midpoint area between the adjacent pads 32, for example, and becomes shallower with distance from the midpoint area.

The recess 31x may be formed by isotropic dry etching. The recess 31x may be formed by isotropic plasma etching using, for example, a fluorine-based etching gas such as carbon tetrafluoride.

As described above, the interconnect substrate 2 is structured such that the outer peripheral areas of the lower surfaces of the pads 32 exposed in the recess 31x are roughened to the same extent as the upper surfaces and the side surfaces of the pads 32. This arrangement increases the contact area between the roughened surfaces of the pads 32 and the second insulating layer 15b, thereby further improving the adhesion between the pads 32 and the second insulating layer 15b. In addition, portions of the second insulating layer 15b is wrapped around the lower surfaces of the pads 32, which generates an anchoring effect, thereby further improving the adhesion between the pads 32 and the second insulating layer 15b. Moreover, the distance for the plating solution to reach the adjacent pads 32 is further increased, which further reduces the possibility of short-circuiting between the adjacent pads 32 even if the intrusion of the plating solution occurs.

According to at least one embodiment, adhesion is improved between the pads of electronic components and the insulating layer covering the pads in an interconnect substrate incorporating the electronic components.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood changes, substitutions, and that the various alterations could be made hereto without departing from the spirit and scope of the invention.

The present disclosures non-exhaustively include the subject matter set out in the following clauses.

Clause 1. A method of making an interconnect substrate including:

forming a cavity in a first insulating layer;

providing an electronic component including an insulating substrate and a pad disposed on one side of the insulating substrate, an upper surface of the pad being exposed outside the insulating substrate and an entirety of side surfaces of the pad being covered with the insulating substrate;

placing the electronic component in the cavity such that the pad faces an opening of the cavity;

dry-etching the electronic component placed in the cavity to uncover the entirety or a part of the side surfaces of the pad from the insulating substrate;

roughening the upper surface and the entirety or the part of the side surfaces of the pad exposed outside the insulating substrate; and

arranging a second insulating layer on the first insulating layer and in the cavity, such that the upper surface and the entirety or the part of the side surfaces of the pad are covered with the second insulating layer.

Clause 2. A method of making an interconnect substrate, including:

forming a cavity in a first insulating layer;

providing an electronic component including an insulating substrate and a pad disposed on one side of the insulating substrate, an upper surface of the pad being exposed outside the insulating substrate and an entirety of side surfaces of the pad being covered with the insulating substrate;

dry-etching the electronic component to uncover the entirety or a part of the side surfaces of the pad from the insulating substrate;

placing the electronic component in the cavity after the dry-etching such that the pad faces an opening of the cavity;

roughening the surface upper and the entirety or the part of the side surfaces of the pad exposed outside the insulating substrate;

arranging a second insulating layer on the first insulating layer and in the cavity, such that the upper surface and the entirety or the part of the side surfaces of the pad are covered with the second insulating layer.

Clause 3. The method of making an interconnect substrate as recited in clause 8 or 9, wherein the dry etching is a plasma etching using a fluorine-based etching gas, and the insulating substrate is made of a material having an etching rate higher than an etching rate of the pad in the plasma etching.

What is claimed is:

1. An interconnect substrate comprising:
a first insulating layer having a cavity formed therein;
an electronic component including an insulating substrate and a pad provided on one side of the insulating substrate, the electronic component being arranged in the cavity, with the pad facing an opening of the cavity; and
a second insulating layer disposed on the first insulating layer and in the cavity,
wherein an upper surface and side surfaces of the pad have areas situated outside the insulating substrate,
wherein at least a part of the areas is covered with the second insulating layer, and
wherein a roughness of a surface of the pad covered with the second insulating layer is larger than a roughness of a surface of the pad not covered with the second insulating layer.

2. The interconnect substrate as claimed in claim 1, wherein the pad is formed of a same material as a single seamless structure.

3. The interconnect substrate as claimed in claim 1, wherein a via hole penetrates through the second insulating layer to reach a part of the upper surface of the pad, and the roughness of the surface of the pad covered with the second insulating layer is larger than a roughness of the part of the upper surface of the pad situated in the via hole.

4. The interconnect substrate as claimed in claim 1, wherein an entirety of the side surfaces of the pad is situated outside the insulating substrate and covered with the second insulating layer.

5. The interconnect substrate as claimed in claim 4, comprising two of said pads which are adjacent to each other, wherein a recess for exposing portions of outer peripheral areas of lower surfaces of the pads is provided in the insulating substrate, and an entirety of side surfaces of the pads and the portions of the outer peripheral areas of the lower surfaces are covered with the second insulating layer.

6. The interconnect substrate as claimed in claim 5, wherein in a cross-sectional view, a depth of the recess is deepest in a midpoint area between the pads, and becomes shallower with distance from the midpoint area.

7. The interconnect substrate as claimed in claim 1, wherein the insulating substrate is made of a material having an etching rate higher than an etching rate of the pad in plasma etching using a fluorine-based etching gas.
